(19) United States
(12) Patent Application Publication
(10) Pub. No.: US 2013/0299231 A1
(43) Pub. Date: Nov. 14, 2013

(54) HOLDER OF A PORTABLE ELECTRIC DEVICE

(71) Applicants: Chien Liang LEE, Taipei (TW); Peng Li XU, Shaanxi (CN)

(72) Inventors: Chien Liang LEE, Taipei (TW); Peng Li XU, Shaanxi (CN)

(21) Appl. No.: 13/467,062

(22) Filed: May 9, 2012

(51) Int. Cl. H05K 7/02

(52) U.S. Cl. 174/545

(57) ABSTRACT

A holder of a portable electric device includes a main body formed integrally. The main body has an intermediate portion formed with a recessed wire-collecting portion, having one end provided with a holding portion having an outer wall disposed with a crevice and a wire-positioning hole bored under the crevice, and another end formed with a clamping portion having an outer wall cut with a clamping opening, a crevice, and a wire-positioning hole bored inside the crevice. Thus, the clamping opening can clamp the portable electric device and the holding portion can be fixed on a table top to have the portable electric device positioned obliquely at an appropriate angle for facilitating browsing and operating. Further, the wires of the portable electric device or of its peripheral products can be positioned in the wire-collecting holes and orderly wound on the wire-collecting portion.

### BACKGROUND OF THE INVENTION

1. Field of the Invention

This invention relates to a holder of a portable electric device, particularly to one formed integral with a bar-shaped main body having an intermediate portion formed with a recessed wire-collecting section. The main body further has one end provided with a holding portion having an outer wall cut with a crevice, and a wire-positioning hole bored under the crevice, and another end disposed with a clamping portion having an outer wall cut with a clamping opening, a crevice, and a wire-positioning hole bored inside the crevice. Thus, after the holding portion of the main body is held on a table top, a portable electronic device can be obliquely clamped and positioned in the clamping opening of the main body to attain an appropriate angle for facilitating browsing and operating of the portable electronic device, and the wires of the portable electric device or of its peripheral products can be positioned in the wire-positioning holes and wound and collected on the wire-collecting section of the main body.

2. Description of the Prior Art

Generally, a portable electric device, such as a cellular phone, a portable computer, a game player and so on, is usually held on a user's hand to browse and/or operate so it may cause sway, swing or bounce to affect the user's vision and as a result, it fails to be operated with convenience. In addition, the wires of the portable electric device or of its peripheral products, such as earphones, USB and so on, can hardly be wound and collected respectively, liable to make knots or entanglements.

### SUMMARY OF THE INVENTION

The objective of this invention is to offer a holder of a portable electric device, which can obliquely position the portable electric device thereon to achieve an appropriate angle for browsing and operating of the portable electric device and also facilitates the wires of the portable electric device or of its peripheral products to be orderly collected.

The holder of the portable electric device in the present invention is formed integral with a bar-shaped main body having an intermediate portion provided with a recessed wire-collecting section. The main body further has one end formed with a holding portion having an outer wall cut with a crevice, and a wire-positioning hole bored under the crevice, and another end provided with a clamping portion having an outer wall disposed with a clamping opening and a crevice, and a wire-positioning hole bored inside the crevice.

### BRIEF DESCRIPTION OF DRAWINGS

This invention will be better understood by referring to the accompanying drawings, wherein:

FIG. 1 is a perspective view of a holder of a portable electric device in the present invention;

FIG. 2 is a perspective view of the holder of the portable electric device in a first using condition in the present invention;

FIG. 3 is a perspective view of the holder of the portable electric device in a second using condition in the present invention;

FIG. 4 is a perspective view of the holder of the portable electric device in a third using condition in the present invention;

FIG. 5 is a perspective view of the holder of the portable electric device in a fourth using condition in the present invention; and

FIG. 6 is a perspective view of the holder of the portable electric device in a fifth using condition in the present invention.

### DETAILED DESCRIPTION OF THE PREFERRED EMBODIMENT

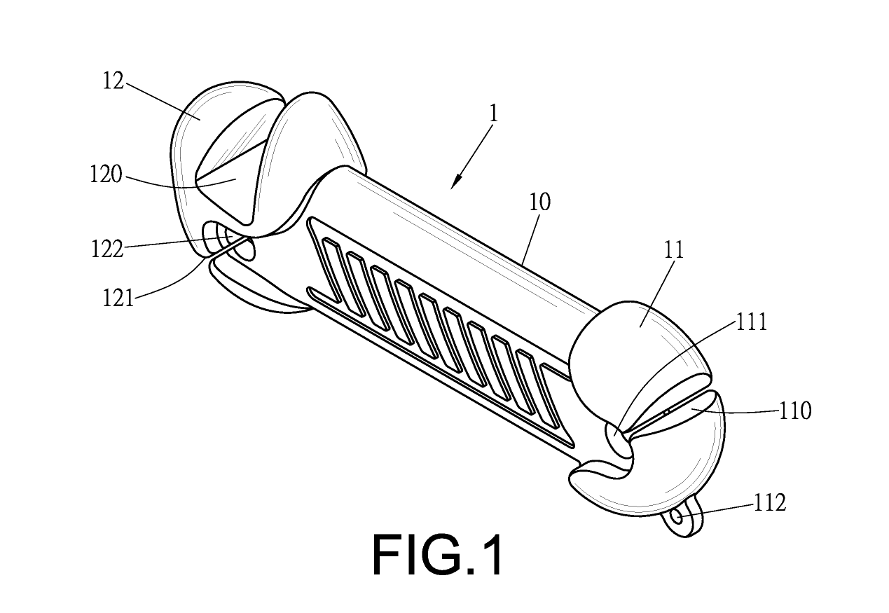

A preferred embodiment of a holder of a portable electric device in the present invention, as shown in FIG. 1, includes a bar-shaped main body 1 formed integrally and made of soft gelatinous substance. The main body 1 is formed with a recessed wire-collecting portion 10 at an intermediate section, having one end provided with a holding portion 11, which has an outer wall cut with a crevice 110, a wire-positioning hole 111 bored under the crevice, and a hanging hole 112. The main body further has another end formed with a clamping portion having an outer wall disposed with a clamping opening 120, a crevice 121, and a wire-positioning hole 122 bored inside the crevice 121.

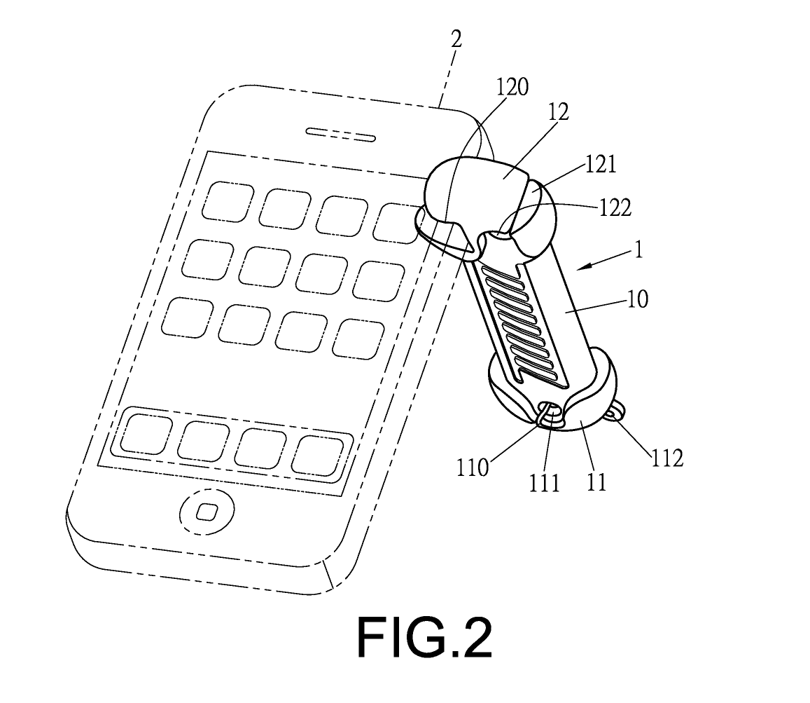

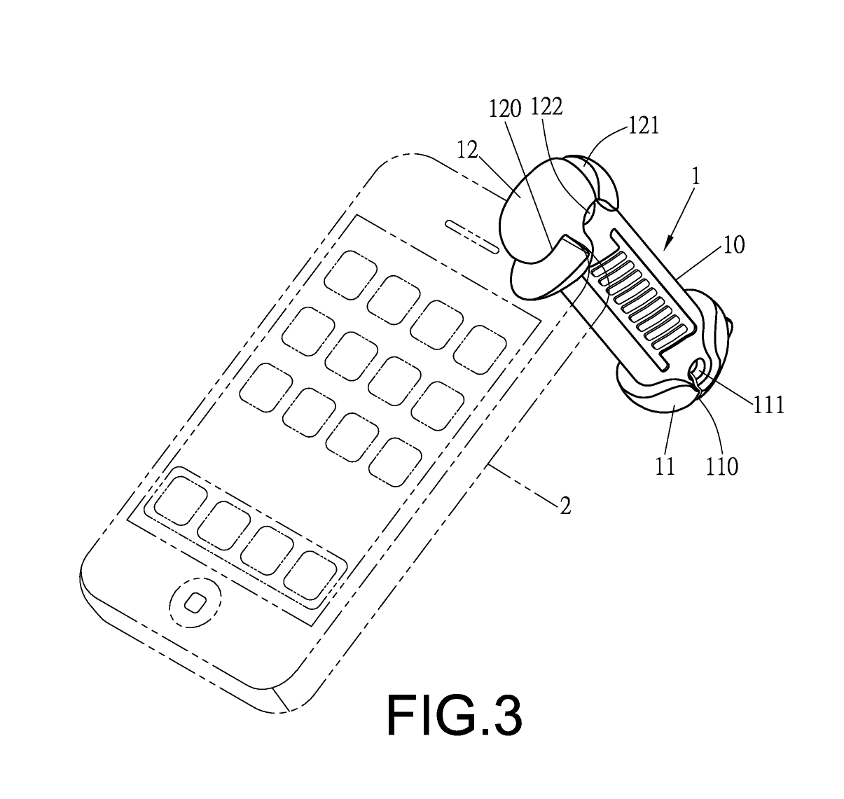

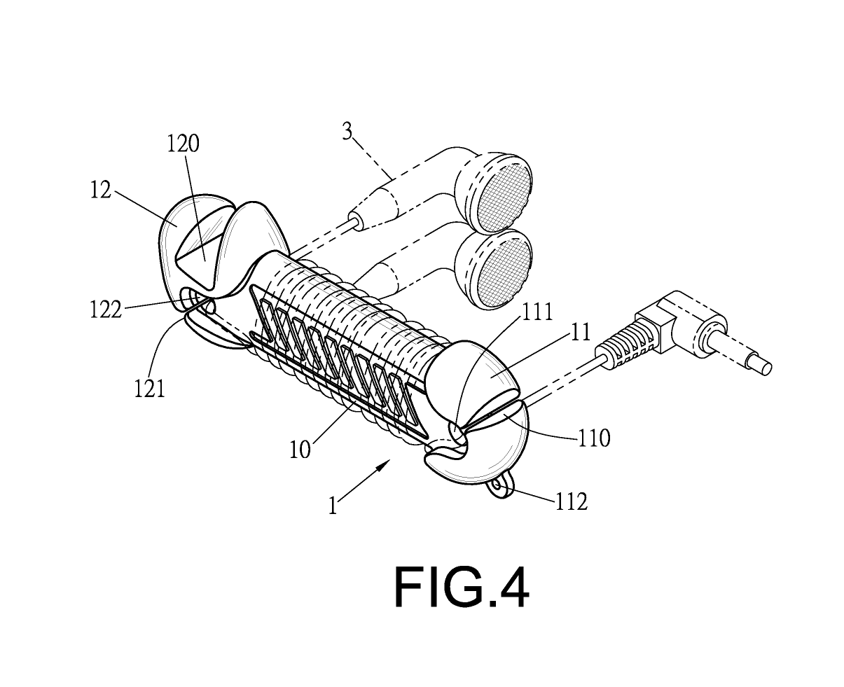

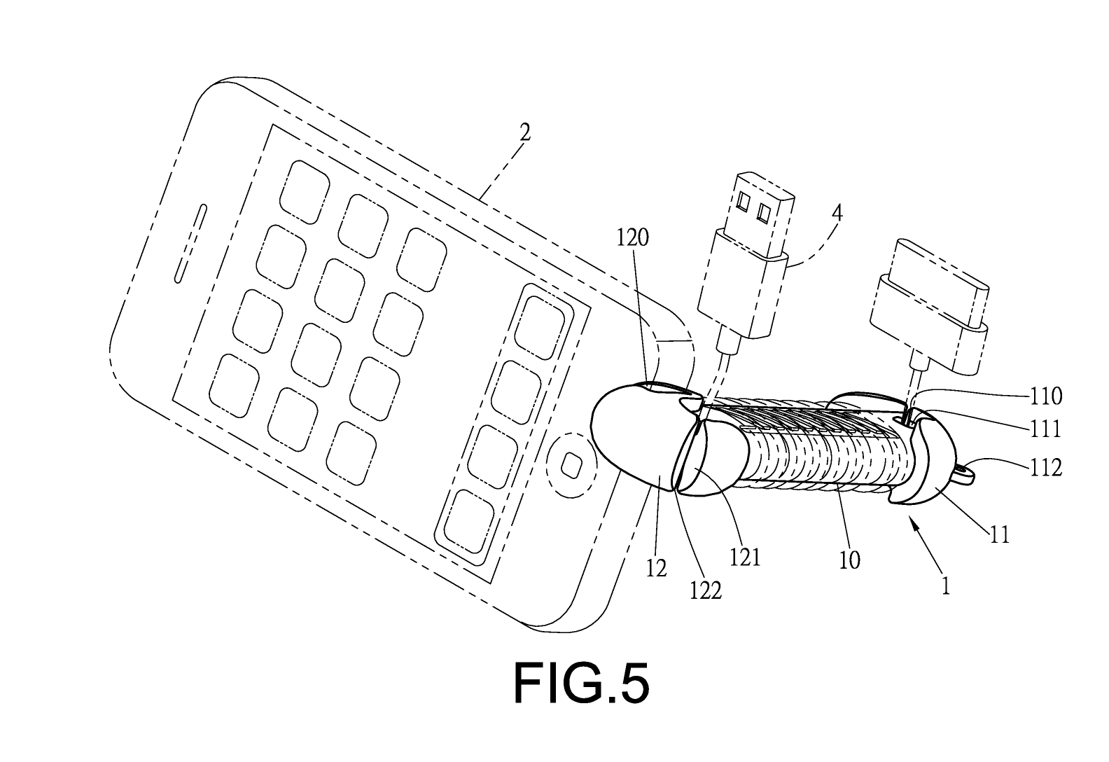

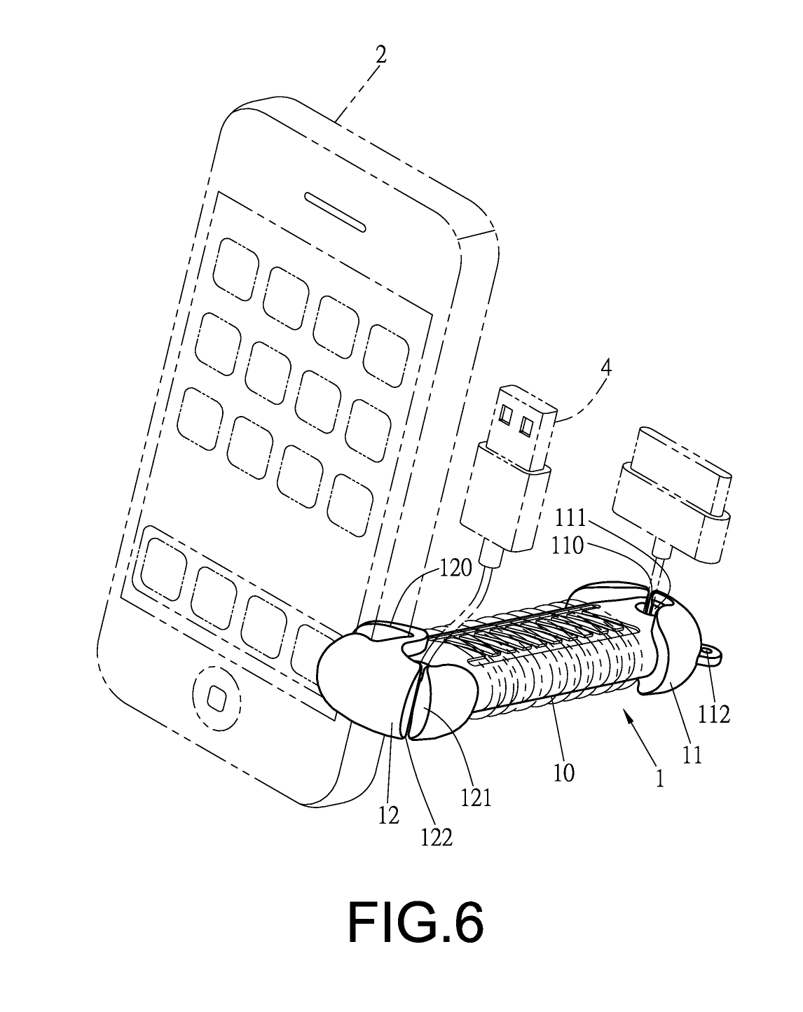

In using, referring to FIGS. 2-6, a portable electric device, such as a cellular phone, a portable computer, a game player and so on, can be clamped in the clamping opening 120 of the main body 1 and after the holding portion 11 of the main body 1 is fixed on a table top, the portable electric device can be obliquely positioned at an appropriate angle so as to facilitate browsing and operating of the portable electric device. Further, the wires of the portable electric device or of its peripheral products, such as earphones shown in FIG. 4, USB (Universal Serial Bus) and so on, can be deposited in the wire-positioning holes 110, 121 and wound around the wire-collecting section 10 of the main body 1 to be collected thereon. Specifically, the clamping opening 120 of the main body 1 can function to clamp the portable electric device like a cellular phone 2, the holding portion of the main body 1 can be held on a table top, and the wires of the portable electric device or of its peripheral products, such as the transmission lines 4 of USB, as shown in FIGS. 5 and 6, can be put into the wire-positioning holes 111, 122 through the crevices 110, 121 and then wound and collected on the wire-collecting section 10 of the main body 1, facilitating the wires to be orderly collected and enabling the portable electric device to be operated at an appropriate angle.

While the preferred embodiment of the invention has been described above, it will be recognized and understood that various modifications may be made therein and the appended claims are intended to cover all such modifications that may fall within the spirit and scope of the invention.

What is claimed is:

1. A holder of a portable electric device comprising a bar-shaped main body formed integrally, said main body having an intermediate portion formed with a recessed wire-collecting section, said main body having one end provided with a holding portion, said holding portion having an outer wall cut with a crevice, a wire-positioning hole bored under said crevice, said main body having another end provided with a clamping portion, said clamping portion having an outer wall cut with a clamping opening, a crevice, and a wire-positioning hole. bored inside said crevice

2. The holder of a portable electric device as claimed in claim 1, wherein said main body is made of soft gelatinous substance.

3. The holder of a portable electric device as claimed in claim 1, wherein said holding portion of said main body has an outer edge provided with a hanging hole.
